(19) United States
(12) Patent Application Publication
(10) Pub. No.: US 2026/0304737 A1
(43) Pub. Date: Oct. 1, 2026

(54) Memory Circuitry And Methods Used In Forming Memory Circuitry

(71) Applicant: Micron Technology, Inc., Boise, ID (US)

(72) Inventors: Saurabh Keshav, Boise, ID (US); Alyssa N. Scarbrough, Boise, ID (US); Chris M. Carlson, Nampa, ID (US); Kolya Yastrebenetsky, Boise, ID (US)

(73) Assignee: Micron Technology, Inc., Boise, ID (US)

(21) Appl. No.: 19/092,039

(22) Filed: Mar. 27, 2025

(51) Int. Cl. H10B 12/00

(52) U.S. Cl. CPC H10B 12/30; H10B 12/03; H10B 12/05

(57) ABSTRACT

Memory circuitry comprises two memory-array regions individually comprising vertically-alternating insulative tiers and memory-cell tiers. An intervening region is laterally between the two memory-array regions in an x-direction. A vertical trench is horizontally elongated in the horizontal x-direction in the two memory-array and intervening regions and extends horizontally from the two memory-array regions across the intervening region in the horizontal x-direction. The vertical trench in the intervening region has a narrowest portion in a horizontal y-direction that is narrower than a narrowest portion of the vertical trench in the horizontal y-direction in each of the two memory-array regions. Other embodiments, including method, are disclosed.

### TECHNICAL FIELD

Embodiments disclosed herein pertain to memory circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

Memory cells may be arranged or arrayed in several manners including, for example, in a vertical stack (e.g., along a vertical z direction) comprising a three-dimensional (3D) memory array region having horizontal tiers in which individual memory cells are received (e.g., arrayed in horizontal x and y directions). The stack in the 3D memory array region comprises vertically-alternating insulative tiers and conductive tiers (e.g., as part of memory-cell tiers) that extend into a stair-step region. The stair-step region includes individual “stairs” (alternately termed “steps” or “stair-steps”) that define contact regions of conductive lines of individual of the conductive tiers to which vertical conductive vias can contact to provide electrical access to/from those conductive lines.

### BRIEF DESCRIPTION OF THE DRAWINGS

FIG. 1 is a diagrammatic schematic of a DRAM memory array and peripheral circuitry in accordance with the prior art and in accordance with an embodiment of the invention.

FIG. 2 is an enlargement of a portion of FIG. 1.

FIGS. 3-10 are diagrammatic sectional views of constructions in accordance with embodiments of the invention.

FIGS. 11-21 are diagrammatic sequential sectional and/or enlarged views of the construction of FIGS. 3-10, or portions thereof or alternate and/or additional embodiments, in process in accordance with some embodiments of the invention.

### DETAILED DESCRIPTION OF EXAMPLE EMBODIMENTS

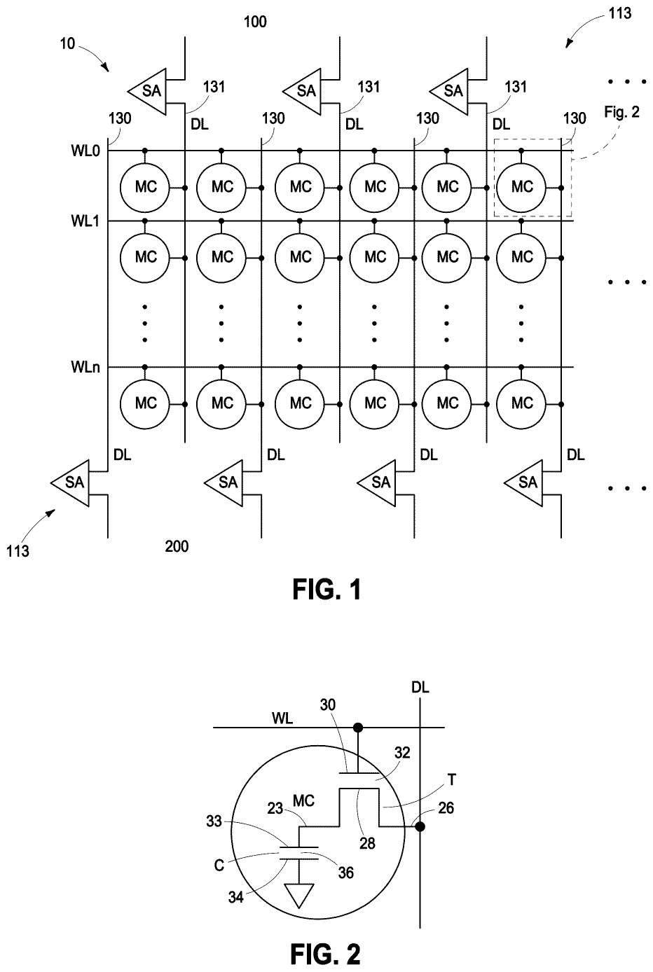

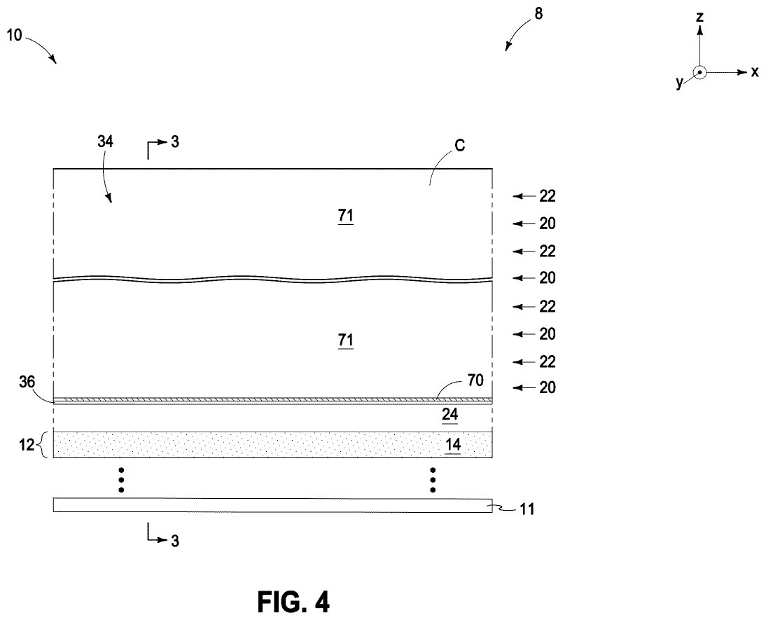

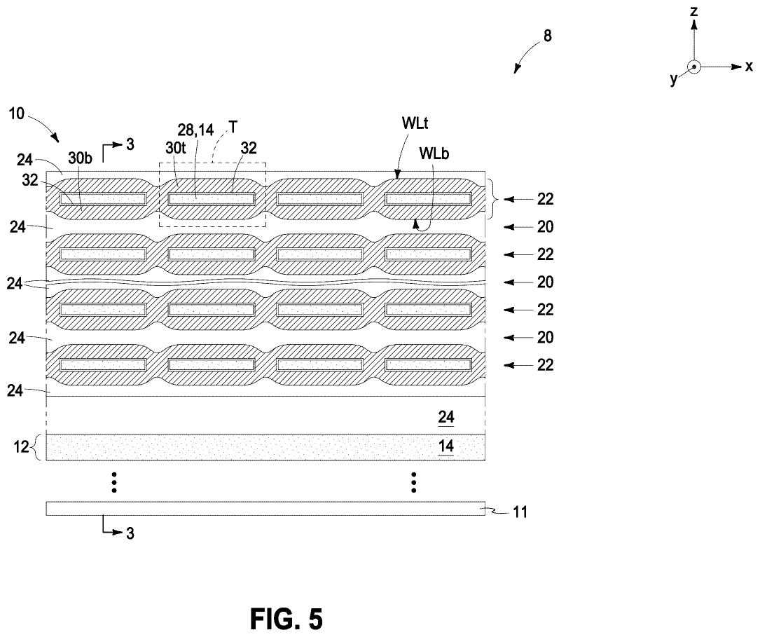

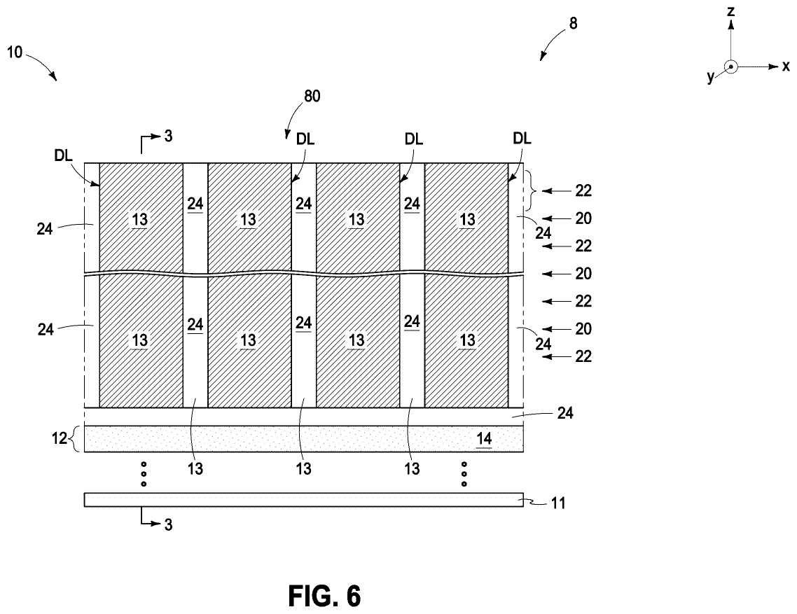

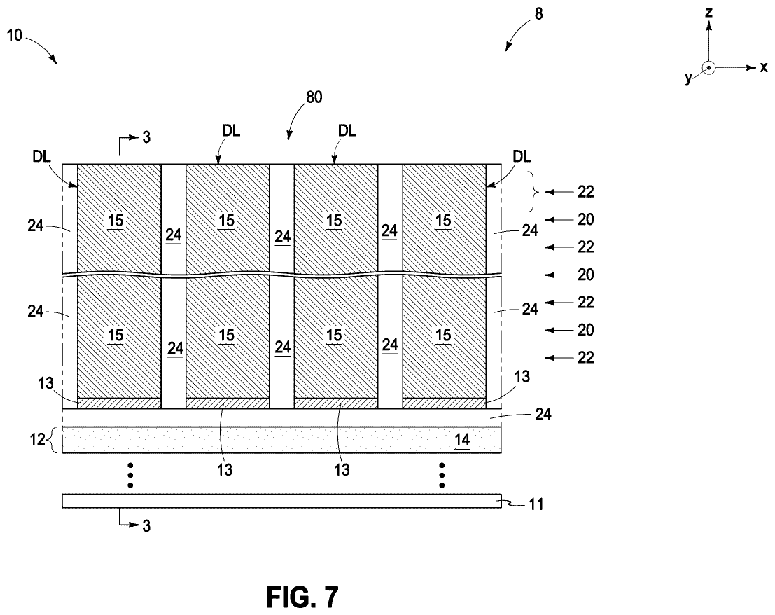

Embodiments of the invention encompass memory circuitry (e.g., DRAM) comprising vertically-stacked memory cells individually comprising a horizontal transistor and a capacitor electrically coupled therewith. Embodiments of the invention also encompass methods used in forming such memory circuitry. Example structure embodiments are first described with reference to FIGS. 1-10.

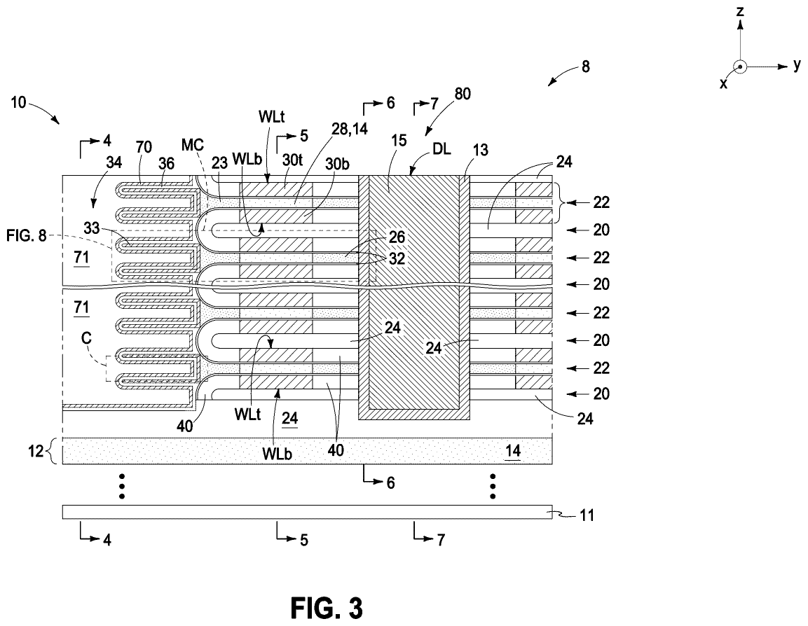

One example prior art schematic diagram of DRAM circuitry, and in accordance with an embodiment of the invention, is shown in FIGS. 1 and 2. FIG. 2 shows example memory cells MC individually comprising a transistor T and a capacitor C. One electrode of capacitor C is directly electrically coupled to a suitable potential (e.g., ground) and the other capacitor electrode is contacted with or comprises one of the source/drain regions of transistor T. The other source/drain region of transistor T is directly electrically coupled with a digitline/sense line 130 or 131 (also individually designated as DL). The gate of transistor T is directly electrically coupled with (e.g., comprises part thereof) a wordline/access line WL. FIG. 1 shows digitlines 130 and 131 extending from one of opposite sides 100 and 200 of a memory array area 10 into a peripheral circuitry area 113 that is aside memory array area 10. Digitlines 130 and 131 individually directly electrically couple with a sense amp SA on opposite sides 100 and 200 of array area 10 within peripheral circuitry area 113. Sense amps SA could be on only one side or all directly above or directly below memory array area 10. Non-schematic structure embodiments as shown herein in FIG. 3+ have the wordlines/access lines running horizontally and the digitlines/sense lines running vertically.

Referring to FIGS. 3-10, an example fragment of a construction 8 comprises two memory-array regions 10 (e.g., individually constituting a “patch”) and an intervening region 19 laterally there-between, both of such being above a base substrate 11. Substrate 11 comprises any one or more of conductive/conductor/conducting, semiconductive/semiconductor/semiconducting, and insulative/insulator/insulating (i.e., electrically herein) materials. Materials may be aside, elevationally inward, or elevationally outward of the FIGS. 3-10-depicted materials. For example, other partially or wholly fabricated components of integrated circuitry may be provided somewhere above, about, or within base substrate 11. Control and/or other peripheral circuitry for operating components within a memory array may also be fabricated and may or may not be wholly or partially within a memory array or sub-array. Further, multiple sub-arrays may also be fabricated and operated independently, in tandem, or otherwise relative one another. As used in this document, a “sub-array” may also be considered as an array. Example construction 8 comprises a semiconductor substrate 12 (e.g., monocrystalline silicon 14) having insulative material 24 there-above (e.g., silicon dioxide and/or silicon nitride).

Memory-array regions 10 of example memory circuitry (e.g., that of or comprising construction 8) comprises vertically-alternating insulative tiers 20 and memory-cell tiers 22 above semiconductor material 14. Example memory-cell tiers 22 comprise memory cells MC and example insulative tiers 20 comprise insulative material 24 (e.g., silicon dioxide). Memory cells MC individually comprise a horizontal transistor T and a capacitor C electrically coupled (e.g., directly) therewith. Horizontal transistor T comprises a gate 30* (e.g., conductive metal material) that is part of one of a plurality of horizontal conductive access lines WL* that individually directly electrically couple together multiple of gates 30* of different ones of horizontal transistors T that are in the same memory-cell tier 22 (an * being used as a suffix to be inclusive of all such same-numerically-designated structures or portions thereof that may or may not have other suffixes). Gate 30* comprises a top gate 30t and a bottom gate 30b having a channel region 28 vertically there-between. Top gate 30t is part of one of a plurality of top horizontal access lines WLt and bottom gate 30b is part of one of a plurality of bottom horizontal access lines WLb. Individual top and bottom access lines WLt and WLb, respectively, are horizontally elongated in a horizontal x-direction and are laterally spaced from one another in a horizontal y-direction that is perpendicular to x-direction. Insulative material 24 of insulative tiers 20 is vertically between top access line WLt and bottom access line WLb of immediately-vertically-adjacent the memory-cell tiers 22 (there being no other such noun [tier] between those that are immediately-adjacent one another). Intervening region 19 is laterally between two memory-array regions 10 in the x-direction.

Example horizontal transistor T comprises a first source/drain region 23 (e.g., conductively-doped silicon), a second source/drain region 26 (e.g., conductively-doped silicon), with channel region 28 being horizontally there-between. Regions 23 and 26 of different immediately-horizontally-adjacent memory cells MC into and out of the plane of the page upon which FIG. 3 lies in a common memory-cell tier 22 (e.g., in the x-direction) may be isolated relative one another by insulative material (not shown). A gate insulator 32 (e.g., dielectric or ferroelectric) is vertically between each of the respective top and bottom gates 30t and 30b and channel region 28. An example insulator material 40 (e.g., silicon nitride) is laterally against lateral sides/edges of gates 30*.

Example capacitor C comprises a storage-node electrode 33, a common electrode 34 (e.g., comprising conductive metal material 70 and conductively-doped polysilicon 71) that is common (directly electrically coupled) to a plurality of capacitors C (at least some, not necessarily all) of memory cells MC, and a capacitor insulator 36 there-between (e.g., dielectric or ferroelectric). Storage-node electrode 33 is directly coupled to first source/drain region 23 of transistor T. Conductively-doped semiconductive material (e.g., conductively-doped epitaxial silicon and not shown) may be between storage-node electrode 33 and first source/drain region 23 (e.g., and such may be considered as a part of either or both).

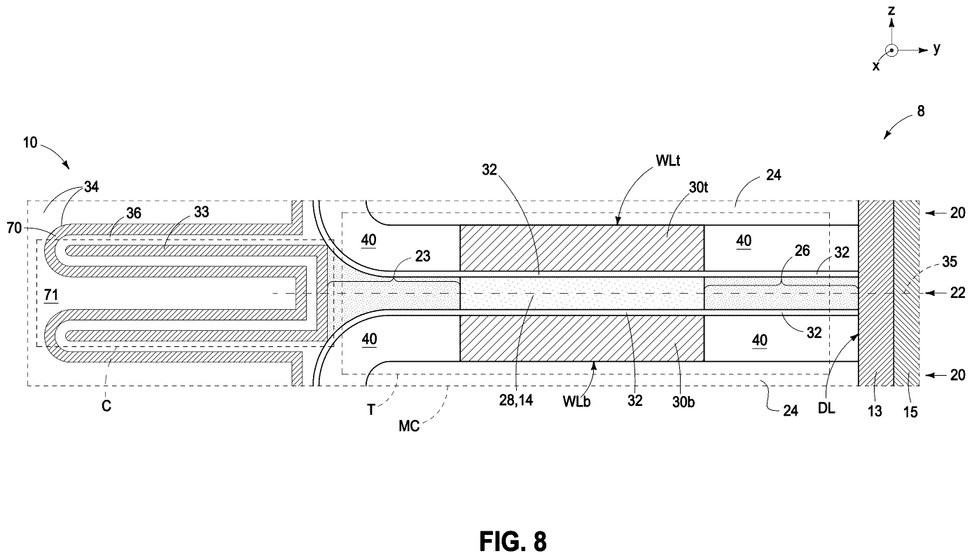

Digitlines DL (e.g., comprising conductive materials 13 and 15) extend through vertically-alternating tiers 20 and 22. Conductively-doped semiconductive material (not shown) may be between/proximate digitline DL and second source/drain region 26. Digitlines DL of different immediately-horizontally-adjacent memory cells MC running into and out of the plane of the page upon which FIG. 3 lies (in the x-direction) may be isolated/spaced relative one another by insulative material 24. Individual second source/drain regions 26 of individual transistors T that are in different memory-cell tiers 22 are electrically coupled (e.g., directly electrically coupled) to individual digitlines DL. Capacitor C and horizontal transistor T may be considered as being horizontally spaced relative one another along horizontal axis 35 (FIG. 8) along the y-direction.

In one embodiment, a vertical trench 80 is in two memory-array and intervening regions 10, 19. Vertical trench 80 is horizontally elongated in the horizontal x-direction in the two memory-array and intervening regions 10, 19 and extends horizontally from two memory-array regions 10 across intervening region 19 in the horizontal x-direction. Digitlines DL are in vertical trench 80 in two memory-array regions 10 and are spaced relative one another in the horizontal x-direction. Insulative material 24 is in vertical trench 80 in intervening region 19 and comprises an insulative wall 72 that extends across intervening region 19 in the horizontal x-direction. Vertical trench 80 has a narrowest portion 92 in the intervening region in the horizontal y-direction that is narrower than a narrowest portion 93 of vertical trench 80 in the horizontal y-direction in each of two memory-array regions 10.

In one embodiment, insulative wall 72 (narrowest portion 92 thereof) includes a y-direction thinnest portion 73 in intervening region 19 that is horizontally elongated in the x-direction and has opposing x-direction ends 74 in intervening region 19 that are each spaced in the x-direction from their closest of two memory-array regions 10. In one embodiment, thinnest portion 73 is centered in the x-direction between two memory-array regions 10 and in one embodiment is of constant y-direction thickness in a horizontal plane (e.g., in one or more horizontal planes in any one or more of tiers 20 and/or 22). Alternately and by way of examples only, thinnest portion 73 may span completely across intervening region 19 in the x-direction and/or be of variable y-direction thickness in a horizontal plane (neither being shown). Additionally, and/or alternately, and by way of examples only, vertical trench 80 in one or both of memory-array regions 10 may be of constant or variable y-direction thickness/width in a horizontal plane and/or span completely or partially across one or both of memory-array regions 10 in the x-direction. Insulative wall 72 and/or vertical trench 80 may taper in y-direction thickness moving deeper into the depicted vertical stack of materials (not shown).

Intervening region 19 may be considered as having an x-direction length L1 between two memory-array regions 10 in a horizontal plane. In some embodiments, thinnest portion 73 has an x-direction length L2 in the horizontal plane that is 15% to 90%, 20% to 80%, or 30% to 75% of x-direction length L1 of intervening region 19.

In one embodiment, access lines WL* extend from two memory-array regions 10 into intervening region 19 and individually have a portion 75 in intervening region 19 having a horizontal outline 76 that curves from the x-direction towards the y-direction and terminates directly against insulative wall 72 in intervening region 19 (e.g., regardless of whether vertical trench 80 is narrowest in the y-direction in intervening region 19 than it is in each of two memory-array regions 10). In some such embodiments, portion 75 has a planar terminus 77 that is parallel the x-direction and/or curves along circular arcs 78. Any other attribute(s) or aspect(s) as shown and/or described herein with respect to other embodiments may be used.

Embodiments of the invention encompass methods used in forming memory circuitry, and by way of example only that incorporate device/structure as referred to above. Nevertheless, the method embodiments may incorporate, form, and/or have any of the attributes described with respect to device embodiments.

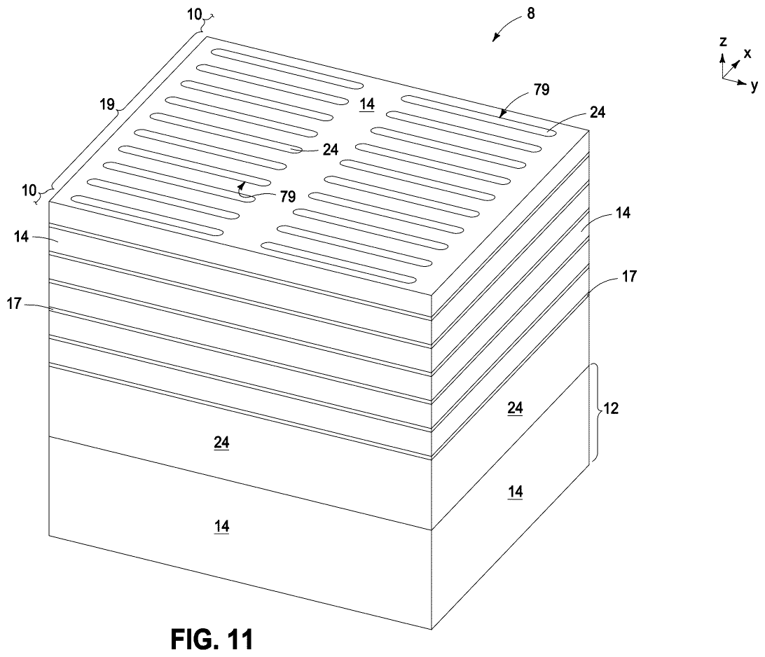

FIGS. 11-21 by way of example sequentially show predecessor constructions in an example method used in forming memory circuitry in accordance with embodiments of the invention. Such memory circuitry ultimately comprises vertically-stacked memory cells individually comprising a horizontal transistor and a capacitor electrically coupled (e.g., directly) therewith.

Referring to FIG. 11, two memory-array regions 10 having an intervening region 19 laterally there-between in a horizontal x-direction have been formed as part of construction 8. Regions 19 and 10 may be indistinguishable at this point of processing. Example construction 8 comprises first material 14 (e.g., epitaxial monocrystalline silicon) and second material 17 that are of different compositions relative one another. An example second material 17 at least predominantly (more than 50% by volume up to and including 100% by volume) is silicon and germanium (e.g., an alloy of silicon and germanium). Isolation walls 79 comprising insulative material 24 and which are horizontally elongated in the y-direction have been formed through the depicted stack of materials (e.g., at least to material/layer 24 that is above semiconductor substrate 12).

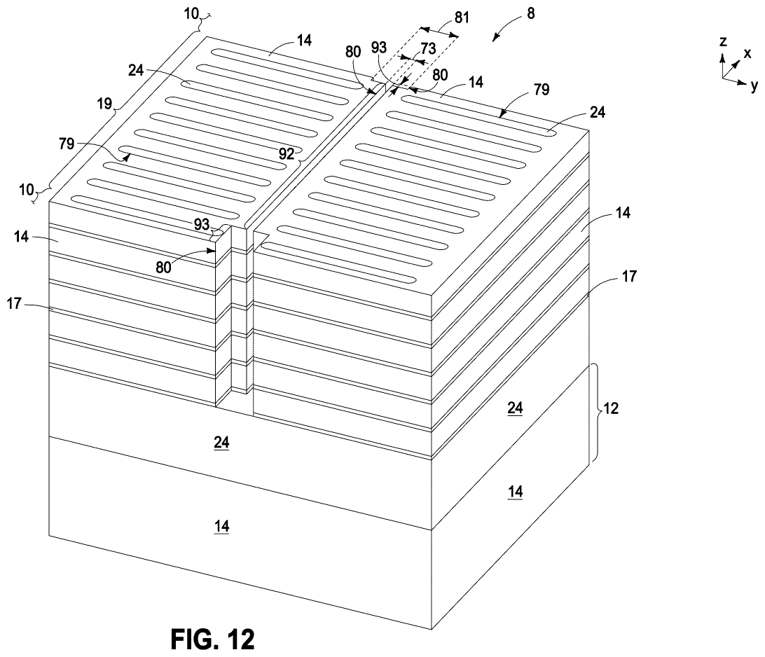

Referring to FIG. 12, a vertical trench 80 has been formed in two memory-array regions 10 and intervening region 19. Vertical trench 80 is horizontally elongated in the x-direction and extends horizontally from two memory-array regions 10 across intervening region 19 in the x-direction. Vertical trench 80 in intervening region 19 has a narrowest portion 92 in the horizontal y-direction that is narrower than a narrowest portion 93 of vertical trench 80 in the horizontal y-direction in each of two memory-array regions 10. Vertical trench 80 may taper in y-direction width moving deeper into the depicted vertical stack of materials (not shown). In some embodiments, narrowest portion 92 has a thinnest portion 73 in a horizontal plane that is 15% to 60%, 15% to 55%, or 15% to 50% of a thinnest portion 81 of vertical trench 80 in the y-direction in each of two memory-array regions 10 in the horizontal plane. Isolation walls 79 may extend to narrowest portion 92 (not shown).

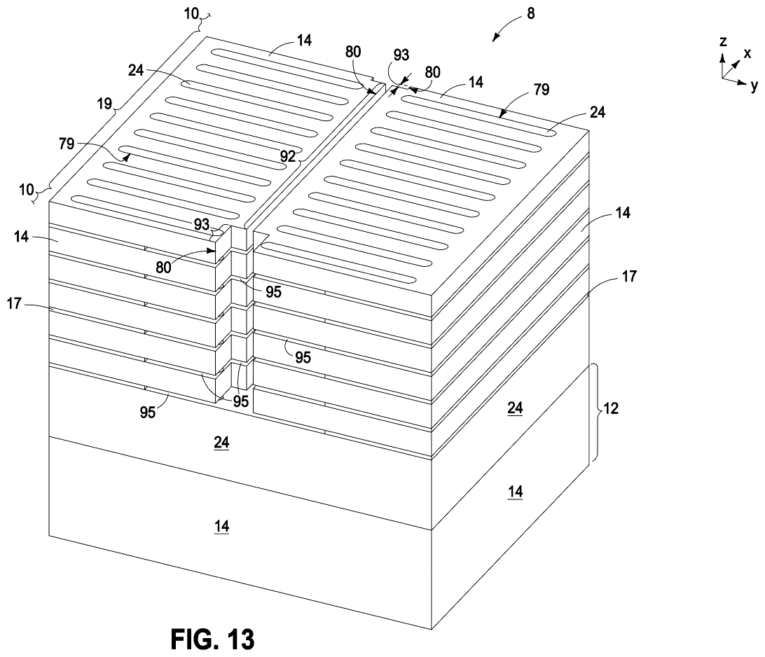

Referring to FIG. 13, and in one embodiment, second material 17 has been recessed (e.g., by selective etching relative to first material 14 through vertical trench 80) forming gaps 95. The y-direction depth of such recessing may be the same or different in wide vs. narrow portions of trench 80.

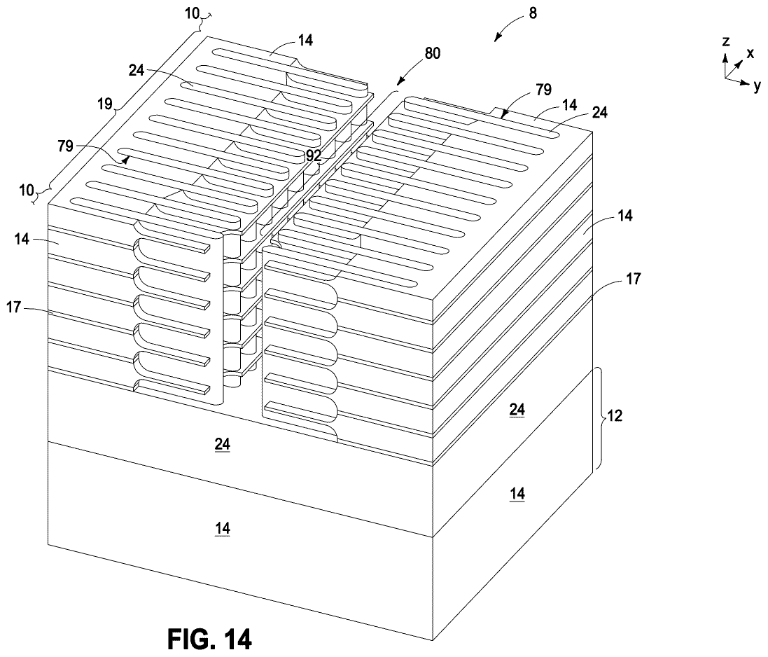

Referring to FIG. 14, and in one embodiment, first material 14 has been thinned (e.g., by selective etching relative to materials 17 and 24). First material 14 may (as shown) or may not (not shown) bridge over the ends of isolation walls 79 depending on whether isolation walls 79 extend to narrowest portion 92.

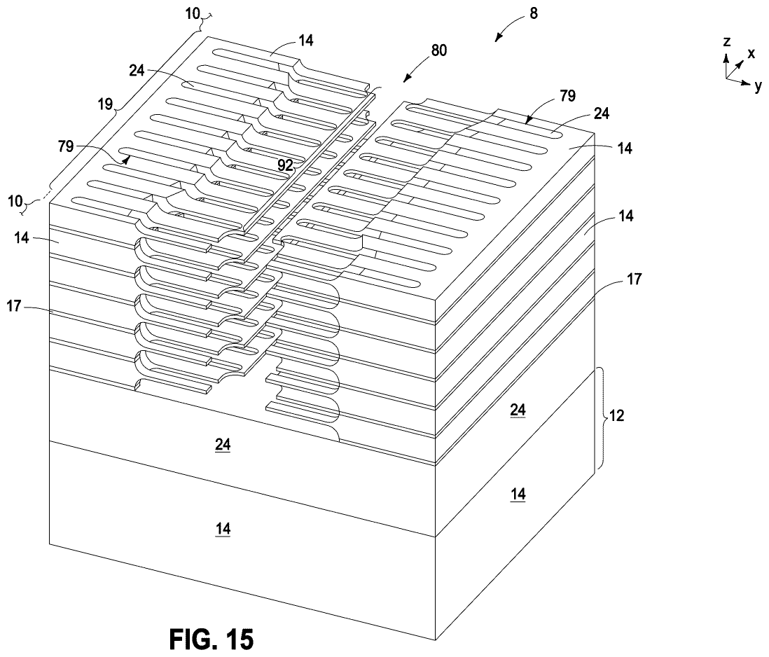

Referring to FIG. 15, and in one embodiment, insulative material 24 of isolation walls 79 has been recessed in the y-direction (e.g., by selective isotropic etching).

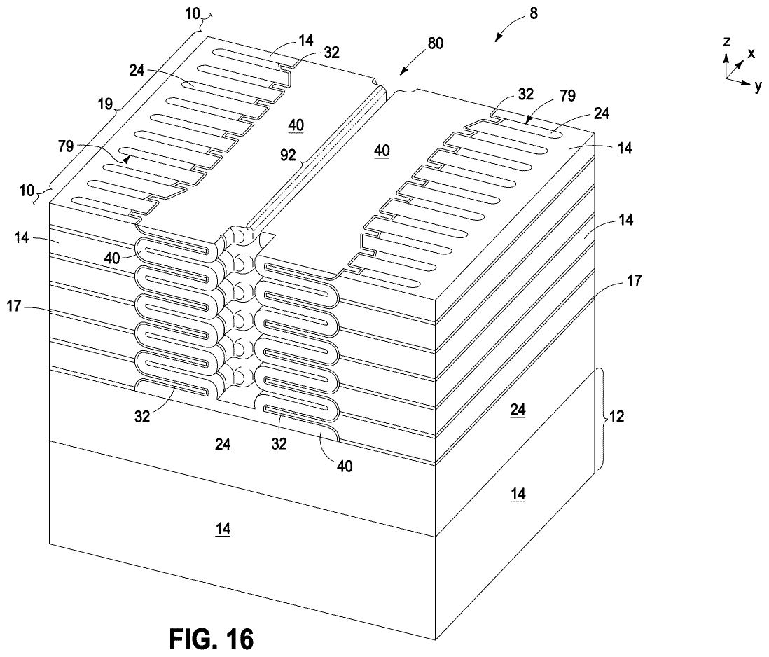

Referring to FIG. 16, and in one embodiment, gate insulator 32 has been formed. This has been followed by forming insulator material 40 to line and less-than-fill narrowest portion 92 of vertical trench 80 in intervening region 19 and to line and less-than-fill the thinnest portion of vertical trench 80 in each of two memory-array regions 10.

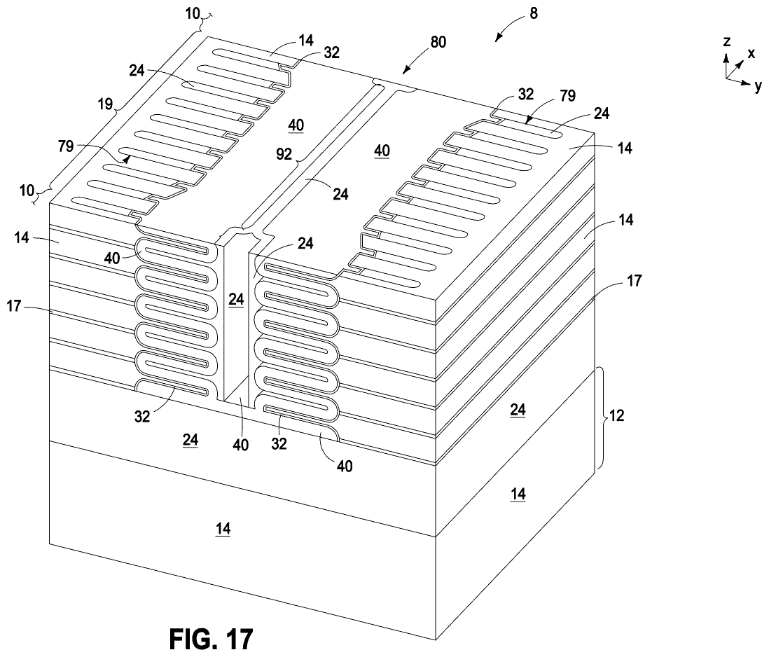

Referring to FIG. 17, insulative material 24 has been formed in vertical trench 80 to fill its narrowest portion 92 in intervening region 19 (fills remaining volume of narrowest portion 92 if insulator material 40 was previously formed therein) and that lines and less-than-fills vertical trench 80 in two memory-array regions 10. Insulative material 24 is also formed horizontally in the y-direction from vertical trench 80 into insulative tiers 20 (e.g., into gaps 95).

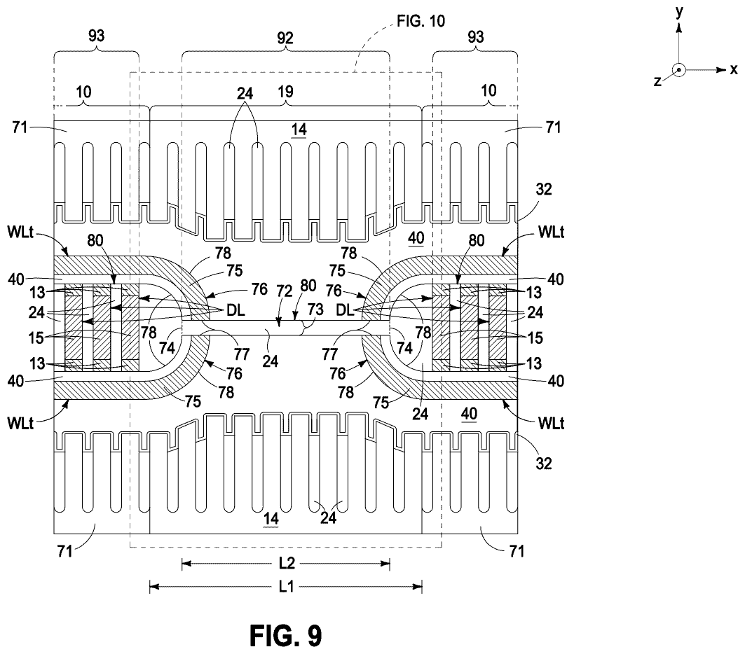

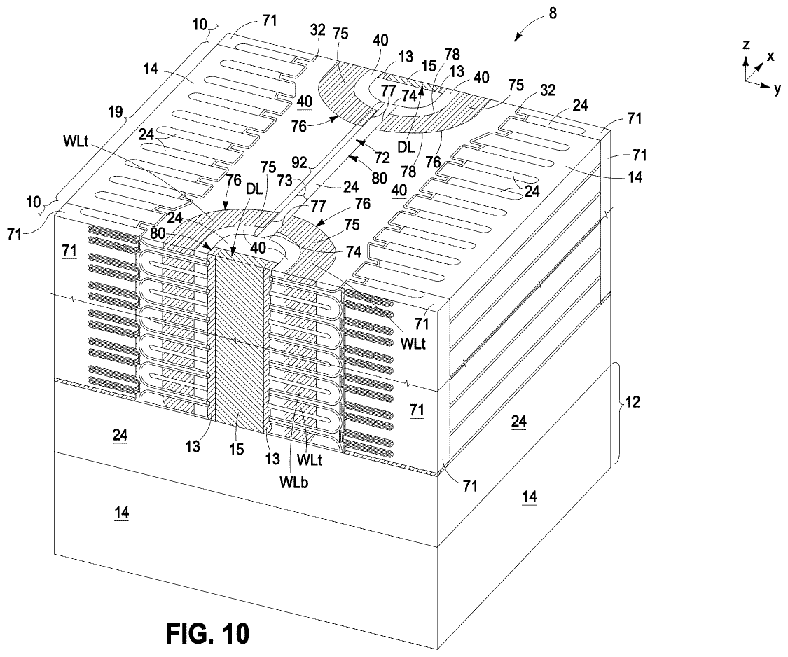

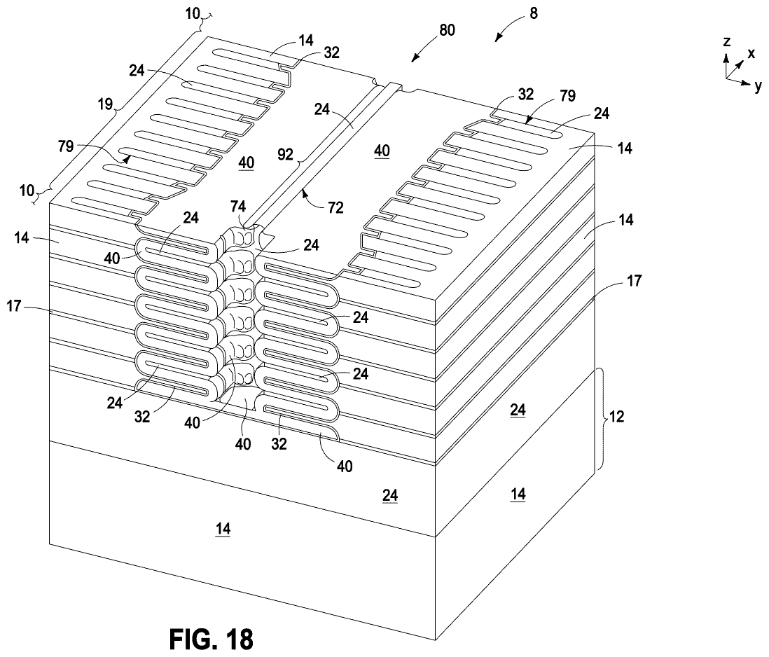

Referring to FIG. 18, insulative material 24 has been removed (e.g., by selective etching) from lining vertical trench 80 in two memory-array regions 10 while leaving insulative material 24 in narrowest portion 92 of vertical trench 80 in intervening region 19. Insulative material 24 left in narrowest portion 92 comprises an insulative wall 72 that is horizontally elongated in the x-direction and extends across intervening region 19 in the x-direction. In one embodiment and as shown, narrowest portion 92 in intervening region 19 has opposing x-direction ends 74 in intervening region 19 that are each spaced in the x-direction from their closest of two memory-array regions 10 (also FIGS. 9 and 10).

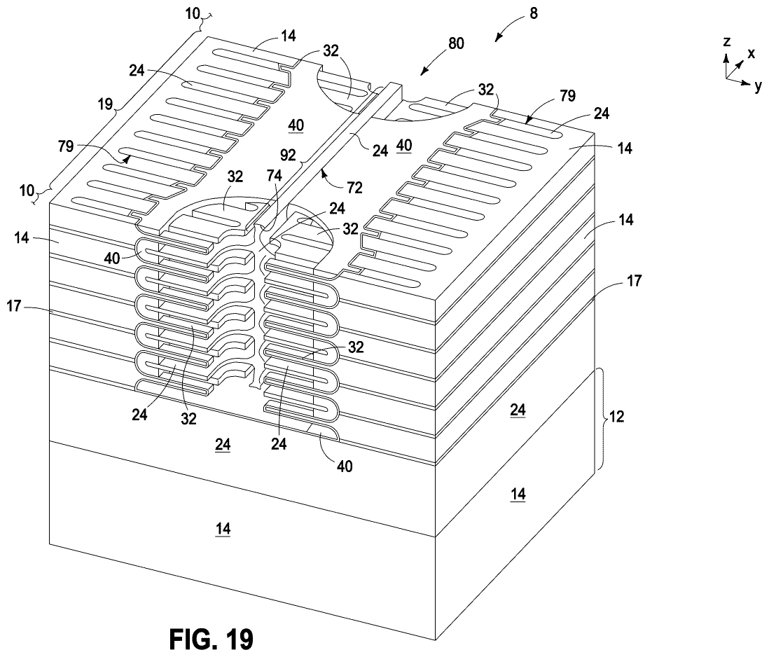

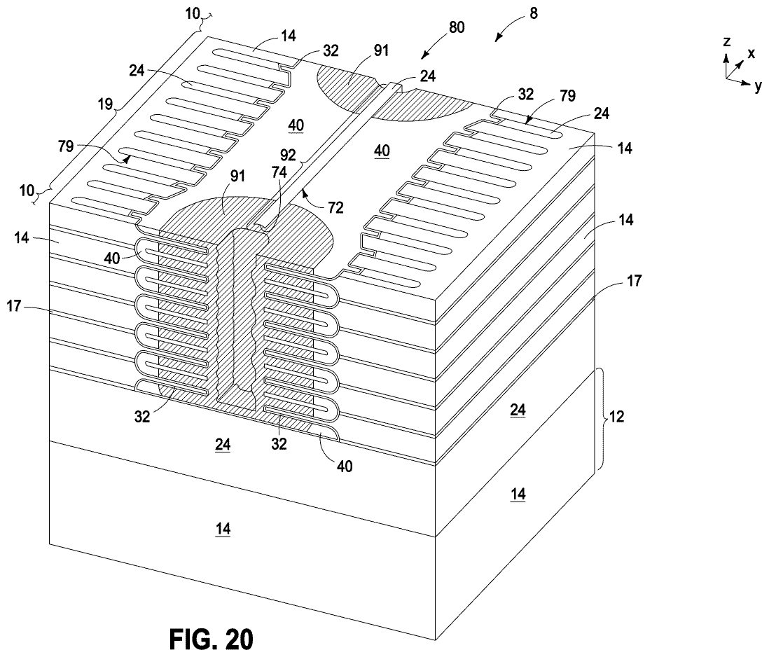

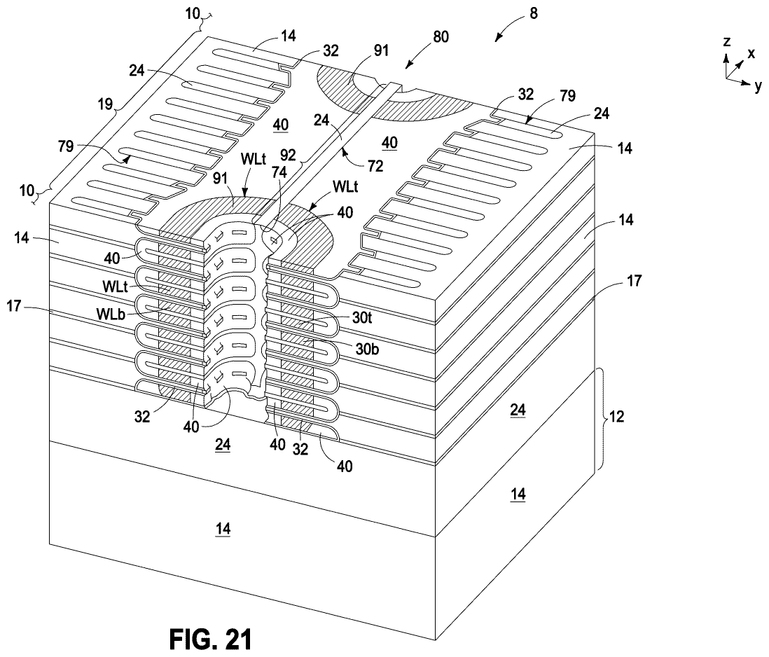

After the removing of insulative material 24, access lines WL* are formed in memory-cell tiers 22 in two memory-array regions 10. For example, and referring first to FIG. 19, insulator material 40 has been recessed (e.g., by selective etching) as shown. FIG. 20 shows forming of conductive material 91 (e.g., conductive metal material) and FIG. 21 shows etching such back to form access lines WL* therefrom, followed by forming insulator material 40 alongside access lines WL*. Previous FIG. 10 shows subsequent formation of a finished construction.

Any other attribute(s) or aspect(s) as shown and/or described herein with respect to other embodiments may be used.

It can be challenging to separate access lines from extending across an intervening region (e.g., 19) that is between two memory-array regions (e.g., 10) and to prevent access lines in the same tier from connecting across a digitline trench (e.g., trench 80) at the end of a memory-array region. A typical way of doing so is to etch through such access lines in a complete vertical stack and which can be difficult. Using a trench 80 as described herein that is narrower in the intervening region as compared to in the two adjacent memory-array regions may be used to preclude such a difficult etch and achieve both such objectives.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The circuitry described herein (e.g., conductive vias thereof) may connect with circuitry that is on either the top or the bottom (i.e., either z-axis side) of a vertical stack regardless of orientation of the construction in three-dimensional space and which is not material to aspects of the inventions disclosed herein. For example, and by way of example only, conductive vias may connect with peripheral control circuitry that is beneath the stack with respect to the orientation shown in the drawings. As an alternate example, and by way of example only, conductive vias may connect with peripheral control circuitry that is above the stack with respect to the shown orientation, for example to another substrate having such circuitry and that is bonded with the top of the stack with respect to the shown orientation. In such alternate example, the construction may be inverted from the shown orientation and then bonded with the other substrate. Further, in such alternate example, electronic components may be fabricated relative to the bottom of the stack with respect to the shown orientation but inverted therefrom during processing. Such electronic components may connect with conductive vias that extend through the stack to the substrate bonded with the other side that has such peripheral control circuitry. Regardless, constructions as shown and described herein may be processed, packaged, and/or mounted in any three-dimensional spatial orientation.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication and as shown in drawings (if any) herein. Further, “vertical” and “horizontal” as used herein are generally perpendicular directions relative one another and independent of orientation of the substrate in three-dimensional space during fabrication and/or in a finished construction. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90°or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### CONCLUSION

In some embodiments, a method used in forming memory circuitry comprises forming two memory-array regions and an intervening region laterally there-between in a horizontal x-direction. A vertical trench is formed in the two memory-array and intervening regions. The vertical trench is horizontally elongated in the horizontal x-direction and extends horizontally from the two memory-array regions across the intervening region in the horizontal x-direction. The vertical trench in the intervening region has a narrowest portion in a horizontal y-direction that is narrower than a narrowest portion of the vertical trench in the horizontal y-direction in each of the two memory-array regions. The horizontal y-direction is perpendicular the horizontal x-direction. Insulative material is formed in the vertical trench that fills its narrowest portion in the intervening region and that lines and less-than-fills the vertical trench in the two memory-array regions. The insulative material is formed horizontally in the horizontal y-direction from the vertical trench into insulative tiers. The insulative tiers vertically alternate with memory-cell tiers. The insulative material is removed from lining the vertical trench in the two memory-array regions while leaving the insulative material in the narrowest portion of the vertical trench in the intervening region. After the removing, access lines are formed in the memory-cell tiers in the two memory-array regions.

In some embodiments, memory circuitry comprises two memory-array regions individually comprising vertically-alternating insulative tiers and memory-cell tiers. An intervening region is laterally between the two memory-array regions in a horizontal x-direction. A vertical trench is in the two memory-array and intervening regions. The vertical trench is horizontally elongated in the horizontal x-direction in the two memory-array and intervening regions and extends horizontally from the two memory-array regions across the intervening region in the horizontal x-direction. Digitlines in the vertical trench in the two memory-array regions are spaced relative one another in the horizontal x-direction. Insulative material in the vertical trench in the intervening region comprises an insulative wall that extends across the intervening region in the horizontal x-direction. The vertical trench in the intervening region has a narrowest portion in a horizontal y-direction that is narrower than a narrowest portion of the vertical trench in the horizontal y-direction in each of the two memory-array regions. The horizontal y-direction is perpendicular the horizontal x-direction.

In some embodiments, memory circuitry comprises two memory-array regions individually comprising vertically-alternating insulative tiers and memory-cell tiers. Memory cells in the memory-cell tiers individually comprise a horizontal transistor having a gate comprising part of one of a plurality of access lines that individually directly electrically couple together multiple of the gates of different ones of the horizontal transistors that are in the same memory-cell tier. The access lines are horizontally elongated in a horizontal x-direction and spaced relative one another in a horizontal y-direction that is perpendicular the horizontal x-direction. An intervening region is laterally between the two memory-array regions in the horizontal x-direction. The access lines extend from the two memory-array regions into the intervening region. An insulative wall is in the intervening region and is horizontally elongated in the horizontal x-direction. The access lines individually have a portion in the intervening region having a horizontal outline that curves from the horizontal x-direction towards the horizontal y-direction and terminates directly against the insulative wall in the intervening region.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry, comprising:
forming two memory-array regions and an intervening region laterally there-between in a horizontal x-direction;
forming a vertical trench in the two memory-array and intervening regions, the vertical trench being horizontally elongated in the horizontal x-direction and extending horizontally from the two memory-array regions across the intervening region in the horizontal x-direction, the vertical trench in the intervening region having a narrowest portion in a horizontal y-direction that is narrower than a narrowest portion of the vertical trench in the horizontal y-direction in each of the two memory-array regions, the horizontal y-direction being perpendicular the horizontal x-direction;
forming insulative material in the vertical trench that fills its narrowest portion in the intervening region and that lines and less-than-fills the vertical trench in the two memory-array regions, the insulative material being formed horizontally in the horizontal y-direction from the vertical trench into insulative tiers, the insulative tiers vertically alternating with memory-cell tiers;
removing the insulative material from lining the vertical trench in the two memory-array regions while leaving the insulative material in the narrowest portion of the vertical trench in the intervening region; and
after the removing, forming access lines in the memory-cell tiers in the two memory-array regions.

2. The method of claim 1 comprising, before forming the insulative material, forming insulator material to line and less-than-fill the narrowest portion of the vertical trench in the intervening region and to line and less-than-fill the narrowest portion of the vertical trench in each of the two memory-array regions.

3. The method of claim 1 wherein,
the insulative material left in the narrowest portion of the vertical trench in the intervening region comprises an insulative wall that is horizontally elongated in the x-direction and extends across the intervening region in the x-direction; and
the narrowest portion of the insulative material that is left in the intervening region has opposing x-direction ends in the intervening region that are each spaced in the x-direction from their closest of the two memory-array regions.

4. The method of claim 1 wherein the intervening region has an x-direction length between the two memory-array regions in a horizontal plane, the narrowest portion of the vertical trench in the intervening region having an x-direction length in the horizontal plane that is 15% to 90% of the x-direction length of the intervening region.

5. The method of claim 1 wherein,
the access lines extend from the two memory-array regions into the intervening region; and
the access lines individually have a portion in the intervening region having a horizontal outline that curves from the x-direction towards the y-direction and terminates directly against the insulative wall in the intervening region.

6. The method of claim 1 wherein the narrowest portion has a thinnest portion in a horizontal plane that is 15% to 60% of a thinnest portion of the vertical trench in the y-direction in each of the two memory-array regions in the horizontal plane.

7. The method of claim 1 wherein the narrowest portion has a thinnest portion in a horizontal plane that is 15% to 55% of a thinnest portion of the vertical trench in the y-direction in each of the two memory-array regions in the horizontal plane.

8. The method of claim 1 wherein the narrowest portion has a thinnest portion in a horizontal plane that is 15% to 50% of a thinnest portion of the vertical trench in the y-direction in each of the two memory-array regions in the horizontal plane.

9. Memory circuitry comprising:
two memory-array regions individually comprising vertically-alternating insulative tiers and memory-cell tiers, an intervening region laterally between the two memory-array regions in a horizontal x-direction;
a vertical trench in the two memory-array and intervening regions, the vertical trench being horizontally elongated in the horizontal x-direction in the two memory-array and intervening regions and extending horizontally from the two memory-array regions across the intervening region in the horizontal x-direction;
digitlines in the vertical trench in the two memory-array regions that are spaced relative one another in the horizontal x-direction, insulative material in the vertical trench in the intervening region that comprises an insulative wall that extends across the intervening region in the horizontal x-direction; and
the vertical trench in the intervening region having a narrowest portion in a horizontal y-direction that is narrower than a narrowest portion of the vertical trench in the horizontal y-direction in each of the two memory-array regions, the horizontal y-direction being perpendicular the horizontal x-direction.

10. The memory circuitry of claim 9 wherein a thinnest portion of the insulative wall in the y-direction in the intervening region is horizontally elongated in the x-direction and has opposing x-direction ends in the intervening region that are each spaced in the x-direction from their closest of the two memory-array regions.

11. The memory circuitry of claim 10 wherein the thinnest portion is centered in the x-direction between the two memory-array regions.

12. The memory circuitry of claim 10 wherein the thinnest portion is of constant y-direction thickness in a horizontal plane.

13. The memory circuitry of claim 10 wherein,
the thinnest portion is centered in the x-direction between the two memory-array regions; and
the thinnest portion is of constant y-direction thickness in a horizontal plane.

14. The memory circuitry of claim 10 wherein the intervening region has an x-direction length between the two memory-array regions in a horizontal plane, the thinnest portion having an x-direction length in the horizontal plane that is 15% to 90% of the x-direction length of the intervening region.

15. The memory circuitry of claim 14 wherein the x-direction length of the thinnest portion is 20% to 80% of the x-direction length of the intervening region.

16. The memory circuitry of claim 15 wherein the x-direction length of the thinnest portion is 30% to 75% of the x-direction length of the intervening region.

17. The memory circuitry of claim 10 wherein,
the intervening region has an x-direction length between the two memory-array regions in a horizontal plane, the thinnest portion having an x-direction length in the horizontal plane that is 15% to 90% of the x-direction length of the intervening region; and
the thinnest portion of the insulative wall in the y-direction in the intervening region in the horizontal plane is 15% to 60% of a thinnest portion of the vertical trench in the y-direction in each of the two memory-array regions in the horizontal plane.

18. The memory circuitry of claim 9 comprising:
memory cells in the memory-cell tiers that individually comprise a horizontal transistor having a gate comprising part of one of a plurality of access lines that individually directly electrically couple together multiple of the gates of different ones of the horizontal transistors that are in the same memory-cell tier, the access lines being horizontally elongated in the x-direction and spaced relative one another in the y-direction;
the access lines extending from the two memory-array regions into the intervening region; and
the access lines individually having a portion in the intervening region having a horizontal outline that curves from the x-direction towards the y-direction and terminates directly against the insulative wall in the intervening region.

19. Memory circuitry comprising:
two memory-array regions individually comprising vertically-alternating insulative tiers and memory-cell tiers, memory cells in the memory-cell tiers that individually comprise a horizontal transistor having a gate comprising part of one of a plurality of access lines that individually directly electrically couple together multiple of the gates of different ones of the horizontal transistors that are in the same memory-cell tier, the access lines being horizontally elongated in a horizontal x-direction and spaced relative one another in a horizontal y-direction that is perpendicular the horizontal x-direction;
an intervening region laterally between the two memory-array regions in the horizontal x-direction, the access lines extending from the two memory-array regions into the intervening region; and
an insulative wall in the intervening region and that is horizontally elongated in the horizontal x-direction, the access lines individually having a portion in the intervening region having a horizontal outline that curves from the horizontal x-direction towards the horizontal y-direction and terminates directly against the insulative wall in the intervening region.

20. The memory circuitry of claim 19 wherein the portion has a planer terminus that is parallel the x-direction.

21. The memory circuitry of claim 19 wherein the curves is along circular arcs.
